(19) United States
(12) Patent Application Publication
(10) Pub. No.: US 2025/0162304 A1
(43) Pub. Date: May 22, 2025

(54) LIGHT IRRADIATING MODULE AND LIGHT IRRADIATING DEVICE

(71) Applicant: HOYA CORPORATION, Tokyo (JP)

(72) Inventor: Hiroaki WATANABE, Tokyo (JP)

(73) Assignee: HOYA CORPORATION, Tokyo (JP)

(21) Appl. No.: 18/888,489

(22) Filed: Sep. 18, 2024

Related U.S. Application Data
(63) Continuation of application No. PCT/JP2023/010488, filed on Mar. 17, 2023.

(30) Foreign Application Priority Data
Mar. 19, 2022 (JP) 2022-044768

(51) Int. Cl. B41F 23/00; H10H 29/14; H10H 29/80

(52) U.S. Cl. CPC B41F 23/00; H10H 29/142; H10H 29/922

(57) ABSTRACT

A light irradiating module comprises: a board; a plurality of wiring patterns which are formed on the board; and a plurality of LED elements which are disposed on the plurality of wiring patterns. The plurality of wiring patterns include: first wiring patterns each of which has a first straight part and a plurality of first protruding parts protruding from the first straight part; and second wiring patterns each of which has a second straight part and a plurality of second protruding parts protruding from the second straight part. The first wiring patterns and the second wiring patterns are disposed alternately, the plurality of first protruding parts and the plurality of second protruding parts adjacent thereto are aligned alternately, and the plurality of LED elements are disposed on the first protruding parts and the second protruding parts.

### CLAIM FOR PRIORITY

This application is a Continuation of PCT/JP2023/010488 filed Mar. 17, 2023, which is expressly incorporated by reference herein in its entirety.

### TECHNICAL FIELD

The present disclosure relates to subject matter contained in Japanese Patent Application No. 2022-044768 (filed on Mar. 19, 2022) which is expressly incorporated by reference herein in its entirety.

The present invention relates to a light irradiating module including a plurality of LED (Light Emitting Diode) elements on a board, and a light irradiating device including the same.

### BACKGROUND ART

As inks for offset sheet printing, ultraviolet curable inks which are cured by irradiation of ultraviolet light have conventionally been used. In addition, as sealants for FPDs (Flat Panel Displays) such as liquid crystal panels and organic EL (Electro Luminescence) panels, ultraviolet curable resins have been used. For curing such ultraviolet curable inks and ultraviolet curable resins, a light irradiating device which irradiates ultraviolet curable inks and ultraviolet curable resins with ultraviolet light are generally used (for example, Patent Literature 1).

As ultraviolet light irradiating devices, lamp-type irradiating devices which use high-pressure mercury lamps, mercury-xenon lamps, and the like as light sources are known; however, in recent years, in response to demands for reduction in electric power consumption, increase in service life, and reduction in size of devices, ultraviolet light irradiating devices which utilize ultraviolet LEDs as light sources instead of the conventional discharge lamps have been put in practice (for example, Patent Literature 1).

FIG. 4A and FIG. 4B are views showing a configuration of a light source unit (ultraviolet light irradiating device) described in Patent Literature 1, and FIG. 4A is a plan view of the light source unit, and FIG. 4B is a view showing a wiring pattern (gray portions) on a board 1 of the light source unit. As shown in FIG. 4A and FIG. 4B, the light source unit described in Patent Literature 1 includes the board 1, a plurality of band-shaped wires 2 disposed on the board 1, and a plurality of LED elements 3 disposed in a row on each band-shaped wire 2. The LED elements 3 on each band-shaped wire 2 are arranged to be displaced, in the wiring direction, from the LED elements 3 on the band-shaped wire 2 adjacent thereto, so that the LED elements 3 are arranged in a staggered manner across the entire board 1. Then, a wire 5 connected to a top electrode 4 of each LED element 3 is connected to a region between the LED elements 3 on the band-shaped wire 2 adjacent thereto.

### CITATION LIST

### Patent Literature

Patent Literature 1: Japanese Patent No. 5803835

### SUMMARY

### Technical Problem

In this way, by arranging LED elements 3 in a staggered manner, when a light source unit moves relative to an irradiation target (print media), it is possible to irradiate the irradiation target with ultraviolet light across a range within which the light source unit moves.

However, the configuration of FIG. 4A and FIG. 4B. of Patent Literature 1 has a problem that the intensity of ultraviolet light cannot be made uniform because the LED elements 3 are arranged such that the LED elements 3 are thinned out in a wiring direction (that is, a left-right direction of FIG. 4A and FIG. 4B) and a direction orthogonal to the wiring direction (that is, an up-down direction of FIG. 4A and FIG. 4B) (with intervals).

Such a problem is particularly significant in the case where an irradiation target does not move at a constant speed relative to the light source unit (that is, in the case where an irradiation target that is fixed is irradiated with ultraviolet light or in the case where an irradiation target that moves at a random speed is irradiated with ultraviolet light), and there is a problem that unevenness is generated in the intensity of ultraviolet light, and an unevenness in hardness of an ultraviolet curable ink or an ultraviolet curable resin is generated.

In addition, such a problem is resolved to some extent by increasing the number of the LED elements 3 on each band-shaped wire 2 and narrowing the arrangement interval; however, in the configuration of FIG. 4A and FIG. 4B, since it is necessary to provide a space (bonding region) for connecting the wire 5 between the LED elements 3 on each band-shaped wire 2, there is a physical limitation in increasing the number of the LED elements 3 in each row.

Moreover, there is a problem that the amount of current to be supplied to the LED elements increases or decreases due to an increase or decrease of the number of the LED elements provided on each band-shaped wire 2.

The present invention has been made in view of such circumstances. Some embodiments provide a light irradiating module (light source unit) which is capable of irradiation with light having a uniform intensity while suppressing the number of LED elements to be connected in parallel. In addition, some embodiments provide a light irradiating device including such a light irradiating module.

### Solution to Problem

In order to achieve the above objects, a light irradiating module of one embodiment comprises: a board which is defined by a first direction and a second direction orthogonal to the first direction; a plurality of wiring patterns which are formed on the board; and a plurality of LED elements which are disposed on the plurality of wiring patterns and emit light in a third direction orthogonal to the first direction and the second direction, wherein the plurality of wiring patterns include: at least one or more first wiring patterns each of which has a first straight part extending in the first direction and a plurality of first protruding parts protruding from the first straight part in a direction opposite to the second direction at a predetermined interval in the first direction; and at least one or more second wiring patterns each of which has a second straight part extending in the first direction and a plurality of second protruding parts protruding from the second straight part in the second direction at a predetermined interval in the first direction, the first wiring patterns and the second wiring patterns are disposed alternately along the direction opposite to the second direction, the plurality of first protruding parts of each first wiring pattern and the plurality of second protruding parts of the second wiring pattern adjacent thereto in the direction opposite to the second direction are aligned alternately along the first direction, the plurality of LED elements are disposed on the first protruding parts and the second protruding parts, and a first electrode of each LED element is electrically connected to the first protruding part or the second protruding part located directly therebelow, and a second electrode of each LED element is electrically connected, via a wire, to the second straight part or the first straight part adjacent thereto in the direction opposite to the second direction.

According to such a configuration, since the LED elements on the board are disposed densely in the first direction, the intensity of ultraviolet light emitted from the LED elements becomes substantially uniform in the first direction. In addition, since the plurality of LED elements aligned in the first direction include a plurality of LED elements connected in parallel on the first wiring pattern and a plurality of LED elements connected in parallel on the second wiring pattern, the number of the LED elements connected in parallel becomes about ½ of the number of the plurality of LED elements aligned in the first direction (that is, the number of the LED elements connected in parallel does not become larger than necessary).

The plurality of LED elements disposed on the plurality of first protruding parts of each first wiring pattern and the plurality of LED elements disposed on the plurality of second protruding parts of the second wiring pattern adjacent thereto in the direction opposite to the second direction may be aligned on a substantially straight line along the first direction.

The plurality of first protruding parts and the plurality of second protruding parts each may have a rectangular shape.

The wiring pattern located farthest in the second direction may form an anode pattern from which current is supplied to the plurality of LED elements, and the wiring pattern located farthest in the direction opposite to the second direction may form a cathode pattern through which return current from the plurality of LED elements flows. In this case, the board may have a pair of through-holes which perpendicularly penetrate the board from the anode pattern and the cathode pattern, respectively. In addition, in this case, the light irradiating module may comprise a pair of fixing members which are inserted through the pair of through-holes, wherein electric power is supplied to the anode pattern and the cathode pattern via the pair of fixing members.

The plurality of LED elements disposed on the first protruding parts may emit light of a first wavelength, and the plurality of LED elements disposed on the second protruding parts may emit light of a second wavelength different from the first wavelength.

In addition, from another aspect, a light irradiating device of another embodiment comprises: the light irradiating module according to any one of the above; and a metal base to which the light irradiating module is fixed. In addition, in this case, the base may have an anode terminal and a cathode terminal which are disposed to penetrate the base and supply electric power to the light irradiating module, the anode terminal be electrically connected to the anode pattern, and the cathode terminal be electrically connected to the cathode pattern.

According to some embodiments as described above, a light irradiating module capable of irradiation with light having a uniform intensity while suppressing the number of LED elements connected in parallel is achieved. In addition, a light irradiating device including such a light irradiating module is achieved.

### BRIEF DESCRIPTION OF DRAWINGS

FIG. 1A and FIG. 1B are views for explaining a schematic configuration of a light irradiating device including LED modules according to an embodiment described herein, with FIG. 1A being a plan view, and FIG. 1B being a sectional view taken along line A-A of FIG. 1A.

FIG. 2 is an exploded perspective view of the light irradiating device of FIGS. 1A and 1B as viewed obliquely from a front side.

FIG. 3A and FIG. 3B are views for explaining a schematic configuration of the LED module according to the embodiment described herein, with FIG. 3A being a plan view, and FIG. 3B being an enlarged view of part B of FIG. 3A.

FIG. 4A and FIG. 4B are views showing a configuration of a light source unit according to a conventional technique, with FIG. 4A being a plan view, and FIG. 4B being a view showing a wiring pattern on a board of the light source unit.

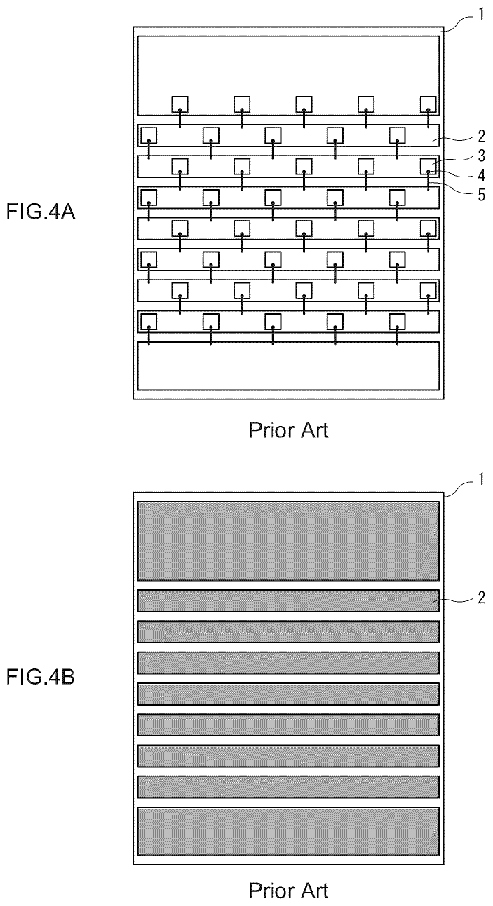

### DESCRIPTION OF EMBODIMENTS

Hereinafter, some embodiments of the present invention will be described in detail with reference to the drawings. Note that in the drawings, the same or corresponding portions are denoted by the same reference signs, and descriptions thereof are not repeated.

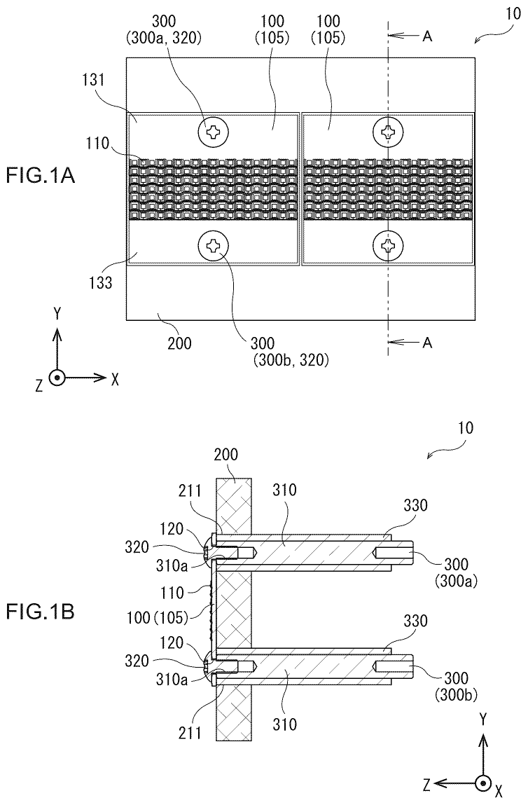

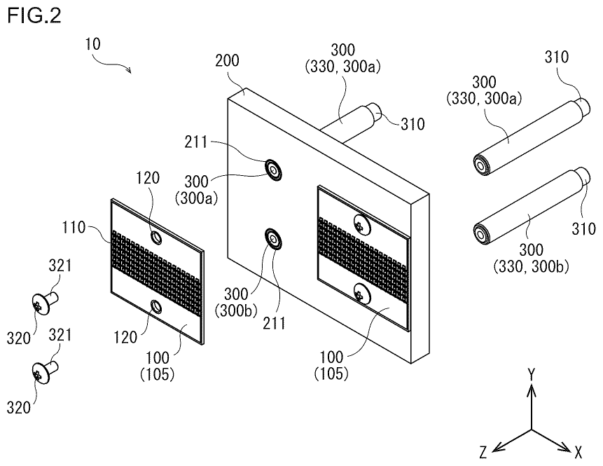

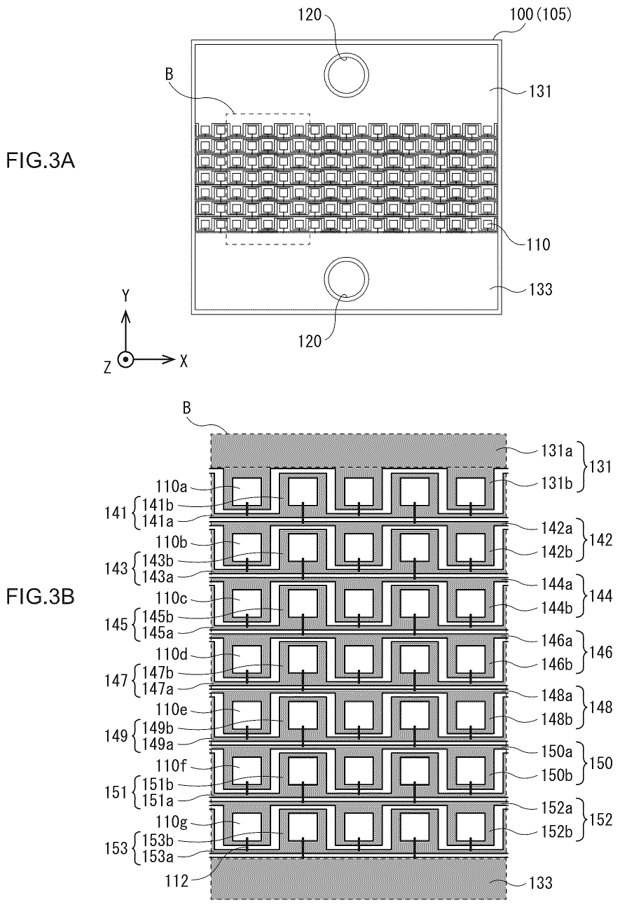

FIG. 1A and FIG. 1B are views for explaining a schematic configuration of a light irradiating device 10 including LED modules 100 (light irradiating modules) according to an embodiment described herein, and FIG. 1A is a plan view, and FIG. 1B is a sectional view taken along line A-A of FIG. 1A. In addition, FIG. 2 is an exploded perspective view of the light irradiating device 10 of FIG. 1A and FIG. 1B as viewed obliquely from a front side. In addition, FIG. 3A and FIG. 3B are views for explaining a configuration of the LED module 100, and FIG. 3A is a plan view, and FIG. 3B is an enlarged view of part B (dashed line part) of FIG. 3A. Note that gray portions of FIG. 3B indicate an anode pattern 131, a cathode pattern 133, and wiring patterns 141 to 153 formed on a board 105 of the LED module 100.

The light irradiating device 10 of the present embodiment is a light source device which is mounted on a printing device, an ultraviolet light irradiating device, or the like and which cures an ultraviolet curable ink or an ultraviolet curable resin, and, for example, is disposed such that the front surface (the surface in which the LED modules 100 are disposed) faces an irradiation target and emits ultraviolet light toward the irradiation target. Note that in the present specification, description is made while the direction in which LED (Light Emitting Diode) elements 110, described later, emit ultraviolet light is defined as a Z-axis direction, the long-side direction of the light irradiating device 10 is defined as an X-axis direction, and the direction orthogonal to the Z-axis direction and the X-axis direction (the short-side direction of the light irradiating device 10) is defined as a Y-axis direction, as shown in FIG. 1A and FIG. 1B. In addition, ultraviolet light is generally considered to mean light having a wavelength of 400 nm or less; however, in the present specification, ultraviolet light is assumed to mean light having a wavelength which is capable of curing an ultraviolet curable ink (for example, a wavelength of 250 to 420 nm).

As shown in FIG. 1A and FIG. 1B and FIG. 2, the light irradiating device 10 of the present embodiment includes two LED modules 100, a heat sink 200 (base), anode terminals 300a and cathode terminals 300b, and the like which supply electric power to each LED module 100, a metal box-shaped case (not shown) which houses these, and the like. Note that in the present specification, the anode terminals 300a and the cathode terminals 300b are also referred to collectively as electrode members 300.

Each LED module 100 includes a rectangular board 105 (circuit board) defined by the X-axis direction and the Y-axis direction and a plurality of LED elements 110 (light-emitting elements) (in FIG. 3A, 19 LED elements 110 (in the X-axis direction)×7 rows (in the Y-axis direction), 133 in total) on the board 105, and in each board 105, a pair of through-holes 120 are formed at positions corresponding to the electrode members 300 (FIG. 1A, FIG. 2, FIG. 3A). Then, in the present embodiment, two LED modules 100 are disposed and fixed on one end surface of the heat sink 200 (FIG. 1A, FIG. 1B, and FIG. 2). Note that in the present embodiment, a heat-dissipation grease (not shown) is applied to the front surface (board mounting surface) of the heat sink 200 and then the board 105 is mounted on the heat sink 200 such that the heat-dissipation grease is placed between the back surface of the board 105 and the heat sink 200, thereby enhancing tight contact between the board 105 and the heat sink 200.

The heat sink 200 is a so-called air-cooling heat sink which is disposed to be in tight contact with the back surface of the board 105 of the LED module 100 and which dissipates heat generated in each LED element 110. The heat sink 200 is made of a material having a favorable thermal conductivity such as aluminum or copper and has a thin-plate shape parallel to the X-Y plane.

In addition, in the heat sink 200, through-holes 211 which perpendicularly penetrate the heat sink 200 from the front surface of the heat sink 200 (in a direction opposite to the Z-axis direction) in such a manner as to communicate with the respective through-holes 120 of the board 105. The electrode members 300 are inserted through the respective through-holes 211 (FIG. 1B, FIG. 2).

Although the electrode members 300 of the present embodiment include the anode terminals 300a which are connected to the anode pattern 131 of the board 105 and the cathode terminals 300b which are connected to the cathode pattern 133, since the specific configurations of these are the same, the cathode terminal 300b is mainly described below as a representative. As shown in FIG. 2, the electrode member 300 (cathode terminal 300b) of the present embodiment includes an electrode bar 310 (electrode terminal), a fixing screw 320 (fixing member), and an insulating sleeve 330 (insulating member).

The electrode bar 310 is a cylindrical metal member, and the insulating sleeve 330 is a cylindrical resin member which covers an outer periphery of the electrode bar 310. In the present embodiment, the electrode bar 310 is inserted through and fixed inside the insulating sleeve 330 (that is, the insulating sleeve 330 is attached to the outer peripheral surface of the electrode bar 310) and is inserted into the through-hole 211 of the heat sink 200 (FIG. 1B, FIG. 2). Then, when the electrode member 300 is attached to the through-hole 211, front ends of the electrode bar 310 and the insulating sleeve 330 are located to be substantially flush with the front surface (mounting surface) of the heat sink 200 or slightly depressed relative to the front surface of the heat sink 200, and base ends of the electrode bar 310 and the insulating sleeve 330 are disposed to protrude from the back surface side of the heat sink 200 (FIG. 1B).

In this way, the light irradiating device 10 of the present embodiment is assembled in the state where the electrode members 300 are attached to the through-holes 211. That is, the heat sink 200 in which the electrode members 300 are attached to the through-holes 211 is prepared, the heat-dissipation grease is applied to the front surface (mounting surface) of the heat sink 200, and each LED module 100 is mounted. Then, positioning is made such that the through-holes 120 of the board 105 are positioned above the electrode bars 310 (on the Z-axis direction side) (that is, the through-holes 120 communicate with the through-holes 211), and the fixing screws 320 are attached to the through-holes 120. Once the fixing screws 320 are attached to the through-holes 120, threaded parts 321 (FIG. 2) of the fixing screws 320 are screwed into threaded hole parts 310a (FIG. 1B formed on inner peripheral surfaces of the electrode bars 310, and the LED modules 100 are held and fixed between head parts of the fixing screws 320 and the heat sink 200 (FIG. 1B). Then, once the LED modules 100 are fixed by the fixing screws 320, the cathode patterns 133 of the board 105 are electrically connected to the electrode bars 310 via the fixing screws 320. In addition, the anode patterns 131 of the board 105 are also electrically connected to the electrode bars 310 via the fixing screws 320. Hence, when drive current for the LED elements 110 is supplied from a driver circuit (not shown) connected to the pair of electrode bars 310, electric power is supplied to the respective LED modules 100 via the anode patterns 131 and the cathode patterns 133.

In this way, in the present embodiment, the electrode members 300 serve for both fixation of the board 105 and supply of the electric power. Hence, there is no need to provide a member dedicated for supplying electric power to the board 105, it becomes possible to reduce the size of the light irradiating device 10. In addition, in the case where the LED module 100 needs to be replaced such as when the LED module 100 has failed as well, the work is only to remove the fixing screws 320 and replace the LED module 100 (that is, there is no need to connect a member dedicated for supplying electric power to the LED module 100 or to route wiring, or the like), and accordingly, it becomes possible to replace the LED module 100 with a simple work.

As shown in FIG. 3A, the board 105 of the LED module 100 of the present embodiment is a rectangular ceramic board formed of aluminum nitride having a high thermal conductivity, for example, where on one end side in the Y-axis direction (the upper side in FIGS. 3A, B), the anode pattern 131, which is electrically connected to the anode terminals 300a, is formed, and on the other end side in the Y-axis direction (the lower side in FIGS. 3A, B), the cathode pattern 133, which is electrically connected to the cathode terminals 300b, is formed. In addition, between the anode pattern 131 and the cathode pattern 133, 13 wiring patterns 141 to 153 are formed in parallel in the X-axis direction.

The anode pattern 131 (first wiring pattern), the cathode pattern 133, and the wiring patterns 141 to 153 are thin films of a metal (for example, copper or gold) for supplying the electric power to the LED elements 110. As shown in FIG. 1B, the anode pattern 131 includes a rectangular band-shaped part 131a (first straight part) extending in the X-axis direction and 10 protruding parts 131b (first protruding parts) protruding in rectangular shapes from the band-shaped part 131a in a direction opposite to the Y-axis direction. In addition, the cathode pattern 133 has a rectangular shape extending in the X-axis direction.

In addition, each wiring pattern 141, 143, 145, 147, 149, 151, 153 (second wiring pattern) includes a straight part 141a, 143a, 145a, 147a, 149a, 151a, 153a (second straight part) extending linearly in the X-axis direction and 9 second protruding parts 141b, 143b, 145b, 147b, 149b, 151b, 153b protruding in rectangular shapes from the straight part 141a, 143a, 145a, 147a, 149a, 151a, 153a in the Y-axis direction.

In addition, each wiring pattern 142, 144, 146, 148, 150, 152 (first wiring pattern) includes a straight part 142a, 144a, 146a, 148a, 150a, 152a (first straight part) extending linearly in the X-axis direction and 9 first protruding parts 142b, 144b, 146b, 148b, 150b, 152b protruding in rectangular shapes from the straight part 142a, 144a, 146a, 148a, 150a, 152a in the direction opposite to the Y-axis direction.

Note that the present embodiment is configured such that each protrusion amount (protrusion distance in the Y-axis direction) and each interval (pitch in the X-axis direction) of the protruding parts 131b, the second protruding part 141b, 143b, 145b, 147b, 149b, 151b, 153b, and the first protruding parts 142b, 144b, 146b, 148b, 150b, 152b are slightly larger than the size of the LED elements 110 and one LED element 110 is disposed on each of the protruding parts 131b, the second protruding parts 141b, 143b, 145b, 147b, 149b, 151b, 153b, and the first protruding parts 142b, 144b, 146b, 148b, 150b, 152b.

Then, in the present embodiment, the protruding parts 131b and the second protruding parts 141b are disposed alternately along the X-axis direction, and LED elements 110a in the first row are disposed side by side in a row along the X-axis direction on the protruding parts 131b and the second protruding parts 141b, respectively.

In addition, the first protruding parts 142b and the second protruding parts 143b are disposed alternately along the X-axis direction, and LED elements 110b in the second row are disposed side by side in a row along the X-axis direction on the first protruding parts 142b and the second protruding parts 143b, respectively.

In addition, the first protruding parts 144b and the second protruding parts 145b are disposed alternately along the X-axis direction, and LED elements 110c in the third row are disposed side by side in a row along the X-axis direction on the first protruding parts 144b and the second protruding parts 145b, respectively.

In addition, the first protruding parts 146b and the second protruding parts 147b are disposed alternately along the X-axis direction, and LED elements 110d in the fourth row are disposed side by side in a row along the X-axis direction on the first protruding parts 146b and the second protruding parts 147b, respectively.

In addition, the first protruding parts 148b and the second protruding parts 149b are disposed alternately along the X-axis direction, and LED elements 110e in the fifth row are disposed side by side in a row along the X-axis direction on the first protruding parts 148b and the second protruding parts 149b, respectively.

In addition, the first protruding parts 150b and the second protruding parts 151b are disposed alternately along the X-axis direction, and LED elements 110f in the sixth row are disposed side by side in a row along the X-axis direction on the first protruding parts 150b and the second protruding parts 151b, respectively.

In addition, the first protruding parts 152b and the second protruding parts 153b are disposed alternately along the X-axis direction, and LED elements 110g in the seventh row are disposed side by side in a row along the X-axis direction on the first protruding parts 152b and the second protruding parts 153b, respectively.

In this way, in the present embodiment, the anode pattern 131 and the wiring patterns 142, 144, 146, 148, 150, 152 (first wiring pattern) having the protruding part 131b and the first protruding parts 142b, 144b, 146b, 148b, 150b, 152b, which protrude in the direction opposite to the Y-axis direction, and the wiring patterns 141, 143, 145, 147, 149, 151, 153 (second wiring pattern) having the second protruding parts 141b, 143b, 145b, 147b, 149b, 151b, 153b, which protrude in rectangular shapes in the Y-axis direction, are disposed alternately in the direction opposite to the Y-axis direction.

In addition, the protruding parts 131b or the first protruding parts 142b, 144b, 146b, 148b, 150b, 152b of each of the anode pattern 131 and wiring patterns 142, 144, 146, 148, 150, 152 (first wiring pattern) and the second protruding parts 141b, 143b, 145b, 147b, 149b, 151b, 153b of each of the wiring patterns 141, 143, 145, 147, 149, 151, 153 (second wiring pattern) adjacent thereto in the direction opposite to the Y-axis direction are aligned alternately along the X-axis direction.

Then, in the present embodiment, 10 rows of the protruding part 131b and the first protruding parts 142b, 144b, 146b, 148b, 150b, 152b are aligned in the Y-axis direction, and 9 rows of the second protruding parts 141b, 143b, 145b, 147b, 149b, 151b, 153b are aligned in the Y-axis direction, and the plurality (133) of LED elements 110 on the board 105 are disposed densely in a square lattice as a whole (that is, aligned in the X-axis direction and the Y-axis direction).

Each LED element 110 has, for example, a rectangular outer shape of 2.0 mm (length in the X-axis direction)×2.0 mm (length in the Y-axis direction) in plan view (FIG. 3A, B), and includes a cathode terminal (second electrode) on the upper surface and includes an anode terminal (first electrode) on the lower surface. Then, the anode terminal is joined to the protruding part 131b, the first protruding part 142b, 144b, 146b, 148b, 150b, 152b, or the second protruding part 141b, 143b, 145b, 147b, 149b, 151b, 153b located directly therebelow via a die bonding agent (not shown). The die bonding agent is a member for mechanically or electrically joining the LED element 110 and the wiring pattern 141 to 153 or anode pattern 131, and a silver (Ag) paste having electrical conductivity is used, for example. In addition, the cathode terminal of each LED element 110 is electrically connected, via a wire 112, to the straight part 141a to 153a of the wiring pattern 141 to 153 or the cathode pattern 133 adjacent thereto in the direction opposite to the Y-axis direction.

In this way, in the present embodiment, since the LED element 110 is disposed on each of the protruding part 131b, the first protruding parts 142b, 144b, 146b, 148b, 150b, 152b, and the second protruding parts 141b, 143b, 145b, 147b, 149b, 151b, 153b, the LED elements 110 are disposed densely in a square lattice as a whole (that is, aligned in the X-axis direction and the Y-axis direction).

Hence, the intensity of ultraviolet light emitted from the LED elements 110 becomes substantially uniform in the X-axis direction and the Y-axis direction.

Therefore, even in the case where an irradiation target does not move at a constant speed relative to the LED module 100 (that is, in the case where an irradiation target that is fixed is irradiated with ultraviolet light or in the case where an irradiation target that moves at a random speed is irradiated with ultraviolet light), unevenness is not generated in the intensity of ultraviolet light, or unevenness in hardness of an ultraviolet curable ink or an ultraviolet curable resin on an irradiation target is not generated.

In addition, in the present embodiment, although the number of the LED elements 110a to 110g in each row is 19, the LED elements 110a to 110g of each row include 10 LED elements 110 which are disposed on and connected in parallel to the protruding part 131b or the first protruding part 142b, 144b, 146b, 148b, 150b, 152b and 9 LED elements 110 which are disposed on and connected in parallel to the second protruding part 141b, 143b, 145b, 147b, 149b, 151b, 153b. For this reason, the number of the LED elements 110 connected in parallel does not become larger than necessary (because the number is about ½ as compared with the case where 19 LED elements 110 are connected in parallel. Thus, the total sum of the drive current (If) of the LED elements 110 (that is, consumed current) does not become large, and also the size of a power supply device for supplying drive current does not become large.

In addition, in the present embodiment, although the wiring pattern 142, 144, 146, 148, 150, 152 (first wiring pattern) and the wiring pattern 141, 143, 145, 147, 149, 151, 153 (second wiring pattern) which are adjacent to each other in the direction opposite to the Y-axis direction are successively connected in series, since the potential difference between adjacent patterns is an operating voltage (about 4 to 5 V) for one LED element 110, the possibility that migration is generated between adjacent patterns also is lowered.

The above description is provided for explaining the embodiments of the present invention, but the present invention should not be limited to the configurations of the aforementioned embodiments, but may be modified in various ways within the scope of the technical idea.

For example, although in the LED module 100 of the present embodiment, 40 LED elements 110 are disposed densely in a square lattice such that there are 19 LED elements 110 (X-axis direction)×7 rows (Y-axis direction), the number of the LED elements 110 and the number of rows are not limited and can be selected as appropriate in accordance with the specifications.

In addition, the LED elements 110 do not necessarily have to be disposed densely in a square lattice. For example, a configuration may be employed in which the length of each of the protruding part 131b and the first protruding parts 142b, 144b, 146b, 148b, 150b, 152b in the Y-axis direction and the length of each of the second protruding parts 141b, 143b, 145b, 147b, 149b, 151b, 153b in the Y-axis direction are set to be long, and the LED elements 110 are disposed such that the positions, in the Y-axis direction, of the LED elements 110 disposed in each protruding part 131b or first protruding part 142b, 144b, 146b, 148b, 150b, 152b and the positions, in the Y-axis direction, of the LED elements 110 disposed in each second protruding part 141b, 143b, 145b, 147b, 149b, 151b, 153b are different from each other. Such a configuration increases the degree of freedom in arrangement of the LED elements 110 in the Y-axis direction, making it possible to flexibly deal with change in specifications or change in design of the LED modules 100.

In addition, the LED elements 110 of the present embodiment have been described as emitting ultraviolet light, but are not limited to such a configuration. For example, the LED elements 110 may emit light in visible range or infrared range.

In addition, the LED elements 110 of the present embodiment do not necessarily have to emit light of one wavelength, and for example, a configuration may be employed in which LED elements that emit light of a first wavelength (for example, 385 nm) are disposed on the respective protruding part 131b and first protruding parts 142b, 144b, 146b, 148b, 150b, 152b and LED elements that emit light of a second wavelength (for example, 405 nm) are disposed on the respective second protruding parts 141b, 143b, 145b, 147b, 149b, 151b, 153b. Such a configuration causes the LED elements of the first wavelength and the LED elements of the second wavelength are disposed alternately in the X-axis direction, making it possible to easily mix light of the first wavelength and light of the second wavelength.

It should be noted that the embodiments disclosed herein should be considered to be exemplary and nonrestrictive in all respects. The scope of the present invention is specified not by the above description but by the scope of claims, and is intended to include all modifications within the meaning and scope equivalent to the scope of claims.

1. A light irradiating module comprising:
a board which is defined by a first direction and a second direction orthogonal to the first direction;
a plurality of wiring patterns which are formed on the board; and
a plurality of LED elements which are disposed on the plurality of wiring patterns and emit light in a third direction orthogonal to the first direction and the second direction, wherein
the plurality of wiring patterns include:
at least one or more first wiring patterns each of which has a first straight part extending in the first direction and a plurality of first protruding parts protruding from the first straight part in a direction opposite to the second direction at a predetermined interval in the first direction; and
at least one or more second wiring patterns each of which has a second straight part extending in the first direction and a plurality of second protruding parts protruding from the second straight part in the second direction at a predetermined interval in the first direction,
the first wiring patterns and the second wiring patterns are disposed alternately along the direction opposite to the second direction,
the plurality of first protruding parts of each first wiring pattern and the plurality of second protruding parts of the second wiring pattern adjacent thereto in the direction opposite to the second direction are aligned alternately along the first direction,
the plurality of LED elements are disposed on the first protruding parts and the second protruding parts, and
a first electrode of each LED element is electrically connected to the first protruding part or the second protruding part located directly therebelow, and a second electrode of each LED element is electrically connected, via a wire, to the second straight part or the first straight part adjacent thereto in the direction opposite to the second direction.

2. The light irradiating module according to claim 1, wherein the plurality of LED elements disposed on the plurality of first protruding parts of each first wiring pattern and the plurality of LED elements disposed on the plurality of second protruding parts of the second wiring pattern adjacent thereto in the direction opposite to the second direction are aligned on a substantially straight line along the first direction.

3. The light irradiating module according to claim 1, wherein the plurality of first protruding parts and the plurality of second protruding parts each have a rectangular shape.

4. The light irradiating module according to claim 1, wherein the wiring pattern located farthest in the second direction forms an anode pattern from which current is supplied to the plurality of LED elements, and the wiring pattern located farthest in the direction opposite to the second direction forms a cathode pattern through which return current from the plurality of LED elements flows.

5. The light irradiating module according to claim 4, wherein the board has a pair of through-holes which perpendicularly penetrate the board from the anode pattern and the cathode pattern, respectively.

6. The light irradiating module according to claim 5, comprising a pair of fixing members which are inserted through the pair of through-holes, wherein electric power is supplied to the anode pattern and the cathode pattern via the pair of fixing members.

7. The light irradiating module according to claim 1, wherein
the plurality of LED elements disposed on the first protruding parts emit light of a first wavelength, and
the plurality of LED elements disposed on the second protruding parts emit light of a second wavelength different from the first wavelength.

8. A light irradiating device comprising:
the light irradiating module according to claim 1; and
a metal base to which the light irradiating module is fixed.

9. The light irradiating device according to claim 8, wherein
the wiring pattern located farthest in the second direction forms an anode pattern from which current is supplied to the plurality of LED elements, and the wiring pattern located farthest in the direction opposite to the second direction forms a cathode pattern through which return current from the plurality of LED elements flows,
the base has an anode terminal and a cathode terminal which are disposed to penetrate the base and supply electric power to the light irradiating module,
the anode terminal is electrically connected to the anode pattern, and
the cathode terminal is electrically connected to the cathode pattern.
